(19) United States
(12) Patent Application Publication
(10) Pub. No.: US 2014/0247677 A1
(43) Pub. Date: Sep. 4, 2014

(54) METHOD OF ACCESSING SEMICONDUCTOR MEMORY AND SEMICONDUCTOR CIRCUIT

(71) Applicant: Samsung Electronics Co., Ltd., Suwon-si (KR)

(72) Inventors: Young-Soo SOHN, Seoul (KR); Chul-Woo PARK, Yongin-si (KR); Uk-Song KANG, Seongnam-si (KR); Jong-Pil SON, Seongnam-si (KR)

(73) Assignee: Samsung Electronics Co., Ltd., Suwon-si (KR)

(21) Appl. No.: 14/081,493

(22) Filed: Nov. 15, 2013

(30) Foreign Application Priority Data
Mar. 4, 2013 (KR) 10-2013-0022854

(51) Int. Cl. G11C 11/4076; G11C 29/48

(52) U.S. Cl. CPC G11C 11/4076; G11C 29/48
USPC 365/200

(57) ABSTRACT

A method of accessing a semiconductor memory is disclosed which includes outputting a row address and an active command to the semiconductor memory; outputting a column address and a read or write command to the semiconductor memory; and outputting a spare access command to the semiconductor memory to access data from a spare memory cell at a timing based on an additive latency of the semiconductor memory. Related devices and systems are also disclosed.

### CROSS-REFERENCE TO RELATED APPLICATIONS

This application claims priority under 35 U.S.C. §119 to Korean Patent Application No. 10-2013-0022854 filed on Mar. 4, 2013, in the Korean Intellectual Property Office, the entire contents of which are hereby incorporated by reference.

### BACKGROUND

The disclosure described herein relates to a method of accessing a semiconductor memory and a semiconductor circuit.

A semiconductor memory device is a memory device which is fabricated using semiconductors such as silicon (Si), germanium (Ge), gallium arsenide (GaAs), indium phosphide (InP), and so on. Semiconductor memory devices may be classified into volatile memory devices and nonvolatile memory devices.

The volatile memory devices may lose stored contents at power-off. The volatile memory devices may include a static RAM (SRAM), a dynamic RAM (DRAM), a synchronous DRAM (SDRAM), and the like. The nonvolatile memory devices may retain stored contents even at power-off. The nonvolatile memory devices may include a read only memory (ROM), a programmable ROM (PROM), an electrically programmable ROM (EPROM), an electrically erasable and programmable ROM (EEPROM), a flash memory device, a phase-change RAM (PRAM), a magnetic RAM (MRAM), a resistive RAM (RRAM), a ferroelectric RAM (FRAM), and so on.

Memory cells can be defected when a semiconductor memory is fabricated. The defected memory cells may not store data normally. A repair technique may be used to make a semiconductor memory including defected memory cells operate normally. With the repair technique, addresses of the defected memory cells may be replaced with addresses of redundant memory cells. When an access to the defected memory cells is requested, redundant memory cells used to replace the defected memory cells may be accessed. Thus, the semiconductor memory may operate normally.

In general, when accessing data from a semiconductor memory device, the semiconductor memory device may need an additional time that compares the received address with a defective address of the semiconductor memory device. Thus, it is required to reduce the time of accessing.

### SUMMARY

One aspect of embodiments of the disclosure is directed to provide a method of accessing a semiconductor memory which comprises outputting a row address and an active command to the semiconductor memory; outputting a column address and a read or write command to the semiconductor memory; and outputting a spare access command to the semiconductor memory to access data from a spare memory cell at a timing based on an additive latency of the semiconductor memory.

Another aspect of embodiments of the disclosure is directed to provide a semiconductor circuit which transfers row addresses, column addresses and commands, comprising a memory configured to store defect information of a memory device; and a command generator configured to output a first access command corresponding to a row address, to compare the row address or the column address with the defect information and to output a spare access command to access data from a spare memory cell associated with the defect information at a timing based on an additive latency.

Another aspect of embodiments of the disclosure is directed to provide a method of operating a memory system, the method which comprises providing an active command and a first row address at a first cycle to a memory device; providing a read or write command and column address at a second cycle after the first cycle to the memory device; determining the first row address at the first cycle or the column address at the second cycle corresponds to a defective address; and providing a spare access command at an nth cycle to access data from a spare memory cell associated with the defective address to the memory device, n being an integer and determined based on an additive latency AL.

With embodiments of the disclosure, a spare access command may be output to a semiconductor memory based on an additive latency AL. Defected memory cells of the semiconductor memory may be replaced with redundant memory cells according to the defect information, and the spare access command may be output without collision with another command. Thus, it is possible to improve the reliability of the semiconductor memory.

### BRIEF DESCRIPTION OF THE FIGURES

Exemplary embodiments will be more clearly understood from the following description with reference to the following figures, wherein like reference numerals refer to like parts throughout the various figures unless otherwise specified, and wherein

FIG. 1 is a block diagram schematically illustrating a memory system according to an exemplary embodiment;

FIG. 2 is a flow chart schematically illustrating a memory access method according to an exemplary embodiment;

FIG. 3 is a flow chart schematically illustrating a method of transferring a spare access command ESC CMD according to one embodiment;

FIG. 4 is a timing diagram schematically illustrating a first embodiment where a memory controller accesses a DRAM;

FIG. 5 is a timing diagram schematically illustrating a second embodiment where a memory controller accesses a DRAM;

FIG. 6 is a timing diagram schematically illustrating a third embodiment where a memory controller accesses a DRAM;

FIG. 7 is a timing diagram schematically illustrating a fourth embodiment where a memory controller accesses a DRAM;

FIG. 8 is a block diagram schematically illustrating a DRAM according to example embodiments;

FIG. 9 is a block diagram schematically illustrating a memory system according to another exemplary embodiment;

FIG. 10 is a block diagram schematically illustrating a memory system according to still another exemplary embodiment; and

FIG. 11 is a block diagram schematically illustrating a computing device according to certain embodiments.

### DETAILED DESCRIPTION OF THE EMBODIMENTS

Various exemplary embodiments will be described in detail with reference to the accompanying drawings. The disclosure, however, may be embodied in various different forms, and should not be construed as being limited only to the illustrated embodiments. Accordingly, known processes, elements, and techniques are not described with respect to some of the embodiments of the disclosure. Unless otherwise noted, like reference numerals denote like elements throughout the attached drawings and written description, and thus descriptions will not be repeated. In the drawings, the sizes and relative sizes of layers and regions may be exaggerated for clarity.

It will be understood that, although the terms “first”, “second”, “third”, etc., may be used herein to describe various elements, components, regions, layers and/or sections, these elements, components, regions, layers and/or sections should not be limited by these terms. Unless indicated otherwise, these terms are only used to distinguish one element, component, region, layer or section from another region, layer or section. Thus, a first element, component, region, layer or section discussed below could be termed a second element, component, region, layer or section without departing from the teachings of the disclosure.

The terminology used herein is for the purpose of describing particular embodiments only and is not intended to be limiting of the disclosure. As used herein, the singular forms “a”, “an” and “the” are intended to include the plural forms as well, unless the context clearly indicates otherwise. It will be further understood that the terms “comprises,” “comprising,” “includes,” and/or “including,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. Also, the term “exemplary” is intended to refer to an example or illustration.

It will be understood that when an element or layer is referred to as being “on”, “connected to”, “coupled to”, or “adjacent to” another element or layer, it can be directly on, connected, coupled, or adjacent to the other element or layer, or intervening elements or layers may be present. In contrast, when an element is referred to as being “directly on,” “directly connected to”, “directly coupled to”, or “immediately adjacent to” another element or layer, there are no intervening elements or layers present.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and/or the present specification and will not be interpreted in an idealized or overly formal sense unless expressly so defined herein.

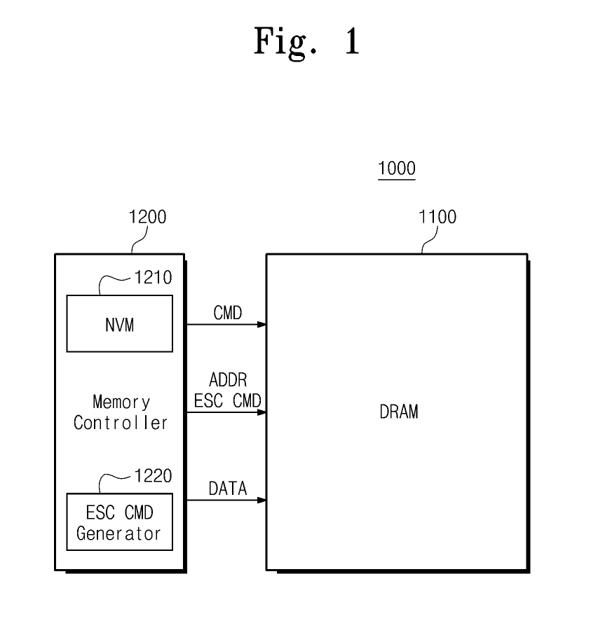

FIG. 1 is a block diagram schematically illustrating a memory system 1000 according to an exemplary embodiment. Referring to FIG. 1, a memory system 1000 may include a Dynamic Random Access Memory DRAM 1100 and a memory controller 1200.

The disclosure will be described based on the DRAM 1100 and the memory controller 1200 adapted to control the DRAM 1100. However, the inventive concept is not limited thereto. The disclosure is applicable to various memories such as an SRAM (Static RAM), an SDRAM (Synchronous DRAM), a ROM (Read Only Memory), a PROM (Programmable ROM), an EPROM (Electrically Programmable ROM), an EEPROM (Electrically Erasable and Programmable ROM), a flash memory, a PRAM (Phase-change RAM), an MRAM (Magnetic RAM), an RRAM (Resistive RAM), an FRAM (Ferroelectric RAM), etc. and memory controllers adapted to control the memories.

The DRAM 1100 may operate in response to a control of the memory controller 1200. The DRAM 1100 may perform a read or write operation according to a control of the memory controller 1200.

In example embodiments, the DRAM 1100 may include one or more DRAM chips. The DRAM 1100 may be a DRAM package including one or more DRAM chips.

In other example embodiments, the DRAM 1100 may include one or more DRAM packages. The DRAM 1100 may be a DRAM module including one or more DRAM packages.

The memory controller 1200 may be adapted to control the DRAM 1100. The memory controller 1200 may control a read or write operation of the DRAM 1100. The memory controller 1200 may send a command CMD and an address ADDR to the DRAM 1100. The memory controller 1200 may issue the command CMD to the DRAM 1100 using a command node or a command line. The memory controller 1200 may issue an address ADDR to the DRAM 1100 using an address node or an address line.

The memory controller 1200 may exchange data with the DRAM 1100. The memory controller 1200 may exchange data with the DRAM 1100 using a data node or a data line.

The memory controller 1200 may send a spare access command ESC CMD to the DRAM 1100. The memory controller may send the spare access command ESC CMD to the DRAM 1100 using the address node or the address line.

The memory controller 1200 may include a nonvolatile memory 1210 and a spare access command generator 1220.

The nonvolatile memory 1210 may store defect information. The defect information may include information associated with addresses of defected memory cells of the DRAM 1100. The nonvolatile memory 1210 may include a fuse circuit or an electrically programmable nonvolatile memory.

The spare access command generator 1220 may generate the spare access command ESC CMD. For example, the spare access command generator 1220 may compare an address received from an external device (e.g., a host) or an address transferred to the DRAM 1100 with defect information stored at the nonvolatile memory 1210. For example, the spare access command generator 1220 may compare a row address or a column address with the defect information stored at the nonvolatile memory 1210.

When the nonvolatile memory 1210 includes information of a corresponding address, the spare access command generator 1220 may generate the spare access command ESC CMD. The spare access command generator 1220 may output the spare access command ESC CMD to the DRAM 1100 through a predetermined address node or pin at a predetermined point of time.

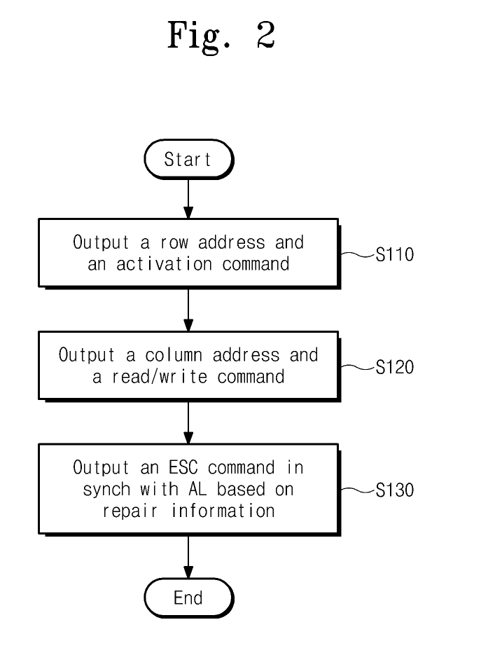

FIG. 2 is a flow chart schematically illustrating a memory access method according to an exemplary embodiment. Referring to FIGS. 1 and 2, in operation S110, a row address and an active command may be issued to a DRAM 1100. A memory controller 1200 may issue the row address and the active command to the DRAM 1100 according to a predetermined schedule or according to a request of an external device (e.g., a host). The memory controller 1200 may receive a command and an address from the external device. The memory controller 1200 may transfer the row address corresponding to the address received from the external device together with the active command to the DRAM 1100.

In operation S120, a column address and a read or write command may be output to the DRAM 1100. The memory controller 1200 may transfer a column address corresponding to the address received from the external device together with the read or write command to the DRAM 1100.

In operation 5130, based on defect information, a spare access command ESC CMD may be output to the DRAM 1100 in synchronization with an additive latency AL. For example, a spare access command ESC CMD may be output to the DRAM 1100 at the end of clock cycle of the additive latency AL. An example of an additive latency AL is described in U.S. Pat. No. 8,358,546 to Yang-Ki Kim et al., assigned to Samsung Electronics Co. Ltd., and entitled “SEMICONDUCTOR DEVICE HAVING ADDITIVE LATENCY,” issued on Jan. 22, 2013. The memory controller 1200 may compare defect information with the address received from the external device or the row or column address output to the DRAM 1100. When the defect information includes information on a corresponding address, that is, when memory cells of the DRAM 1100 to be accessed are defected memory cells, the memory controller 1200 may issue the spare access command ESC CMD to the DRAM 1100. The spare access command ESC CMD may be output in synchronization with the additive latency AL.

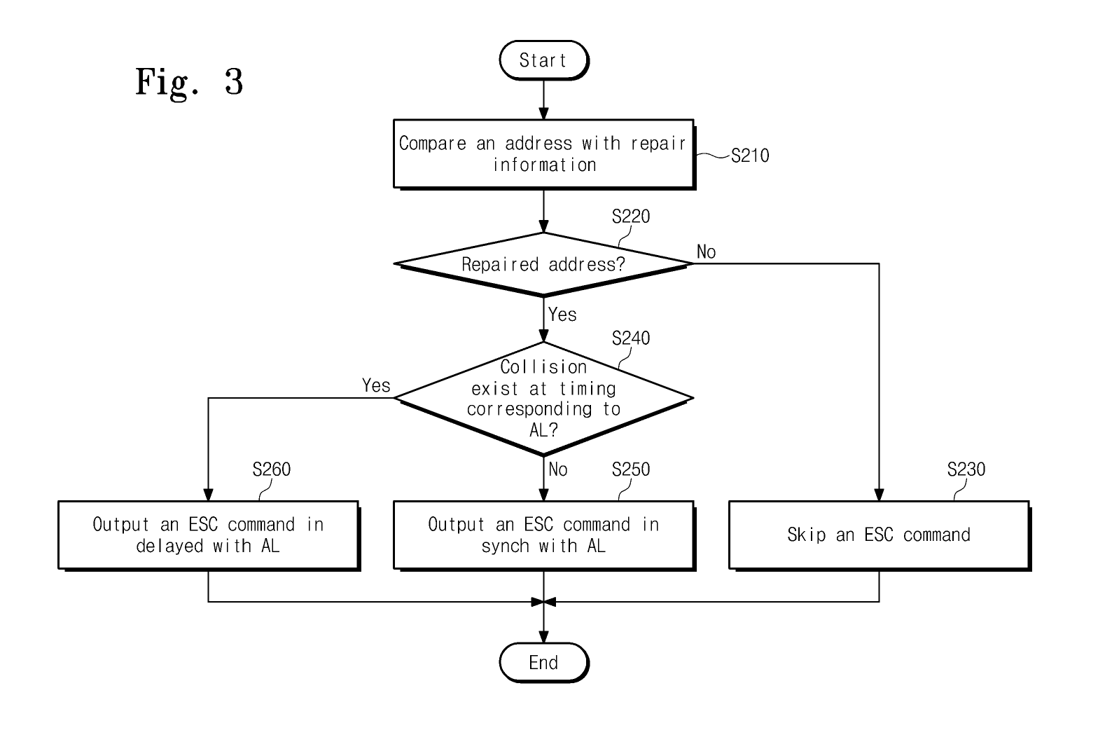

FIG. 3 is a flow chart schematically illustrating a method S310 of transferring a spare access command ESC CMD according to one embodiment. Referring to FIGS. 1 to 3, in operation S210, an address may be compared with defect information. A spare access command generator 1220 may compare an address received from an external device or a row or column address output to a DRAM 1100 with the defect information stored at a nonvolatile memory 1210.

In operation S220, whether it is an associated address may be determined. The spare access command generator 1220 may determine whether information on the compared address corresponds to the defect information. If information on the compared address is not included in the defect information, in operation S230, an issue of a spare access command ESC CMD may be skipped. If information on the compared address corresponds to the defect information, the method may proceed to operation S240.

In operation S240, whether collision exists at timing corresponding to an additive latency AL may be determined. In one embodiment, a first set of address lines of address lines may transfer row addresses or column addresses and at least one of second set of address lines of the address lines different from the first set of address lines may transfer at least one of additional row addresses and the spare access command ESC CMD. For example, the spare access command generator 1220 may output the spare access command ESC CMD at timing corresponding to the additive latency AL (e.g., at the end of clock cycle of the additive latency AL). The spare access command generator 1220 may determine whether a row address is transferred to the DRAM 1100 at the timing corresponding to the additive latency AL through a second address line.

In the event that a row address is not transferred to the DRAM 1100 at the timing corresponding to the additive latency AL through the second address line, that is, in the event that collision does not exist, in operation S250, the spare access command ESC CMD may be output in synchronization with the additive latency AL (e.g., at the end of clock cycle of the additive latency AL). The spare access command generator 1220 may output the spare access command ESC CMD at the timing corresponding to the additive latency AL.

In the event that a row address is transferred to the DRAM 1100 at the timing corresponding to the additive latency AL through the second address line, that is, in the event that collision exists, in operation S260, an output of the spare access command ESC CMD may be delayed with respect to the additive latency AL. The spare access command generator 1220 may output the spare access command ESC CMD to the DRAM 1100 at timing delayed with respect to the additive latency AL.

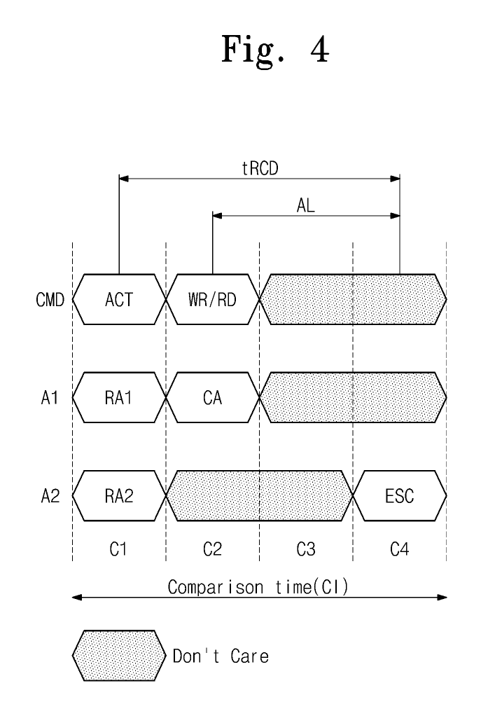

FIG. 4 is a timing diagram schematically illustrating a first embodiment where a memory controller 1200 accesses a DRAM 1100. In FIG. 4, there is illustrated an example where information associated with an address corresponds to defect information and no collision exists (operation S250 of FIG. 3).

Referring to FIGS. 1 and 4, at a first clock cycle C1, a memory controller 1200 may output an active command ACT and row addresses RA1 and RA2 to a DRAM 1100. The row address RA1 may be transferred through a first set of address lines A1 of address lines between the memory controller 1200 and the DRAM 1100. The row address RA2 may be transferred through at least one of second address lines A2 (hereinafter, referred to as a singular address line) of the address lines between the memory controller 1200 and the DRAM 1100.

The DRAM 1100 may select a row of memory cells in response to the row addresses RA1 and RA2 and the active command ACT transferred through the first and second address lines A1 and A2.

At a second clock cycle C2, the memory controller 1200 may output a read or write command WR/RD and a column address CA to the DRAM 1100. The column address CA may be transferred through the first set of address lines A1 of the address lines between the memory controller 1200 and the DRAM 1100.

After the memory controller 1200 outputs the column address CA and the read or write command WR/RD to the DRAM 1100, the DRAM 1100 may select columns of memory cells according to the column address CA and the read or write command WR/RD transferred through the first set of address lines A1 after an additive latency AL elapses. For example, the DRAM 1100 may perform selection and activation of a row of memory cells while the additive latency AL elapses. After the additive latency AL elapses, the DRAM 1100 may select columns of memory cells.

In example embodiments, the additive latency AL may correspond to two clock cycles. Thus, the DRAM 1100 may select columns of memory cells at a fourth clock cycle C4 after the column address CA and the read or write command WR/RD are transferred and two clock cycles elapses.

The memory controller 1200 may compare an address with defect information while the additive latency AL elapses. Since information on the address is included in the defect information, the memory controller 1200 may output a spare access command ESC CMD to the DRAM 1100 at the fourth clock cycle C4 being timing corresponding to the additive latency AL.

In response to the spare access command ESC CMD, the DRAM 1100 may select columns of memory cells. For example, the DRAM 1100 may not select columns of memory cells corresponding to the column address CA, but select columns of memory cells of a spare area associated with the column address CA (e.g., spare memory cells).

As illustrated in FIG. 4, the memory controller 1200 may output the spare access command ESC CMD in synchronization with the additive latency AL. Thus, the address may be compared with the defect information during the additive latency AL. That is, the memory controller 1200 may compare a row or column address with the defect information during a comparison time CI and issue the spare access command ESC CMD according to the comparison result.

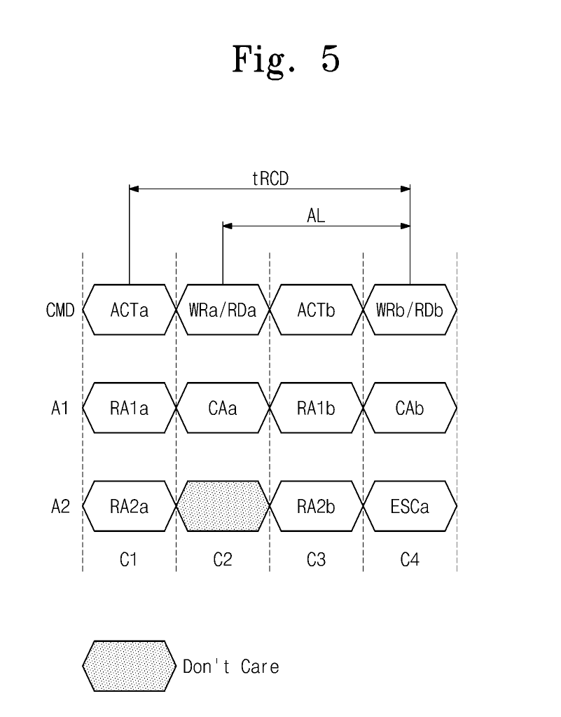

FIG. 5 is a timing diagram schematically illustrating a second embodiment where a memory controller 1200 accesses a DRAM 1100. In FIG. 5, there is illustrated another example where information associated with an address corresponds to defect information and no collision exists (operation S250 of FIG. 3).

Referring to FIGS. 1 and 5, at a first clock cycle C1, a memory controller 1200 may output an active command ACTa and row addresses RA1a and RA2a to a DRAM 1100. The row address RA1a may be transferred through a first set of address lines A1 of address lines between the memory controller 1200 and the DRAM 1100. The row address RA2a may be transferred through a second address line A2 of the address lines between the memory controller 1200 and the DRAM 1100.

At a second clock cycle C2, the memory controller 1200 may output a read or write command WRa/RDa and a column address CAa to the DRAM 1100. The column address CAa may be transferred through the first set of address lines A1 of the address lines between the memory controller 1200 and the DRAM 1100.

At a third clock cycle C3, the memory controller 1200 may output an active command ACTb and row addresses RA1b and RA2b to the DRAM 1100. The row address RA1b may be transferred through the first set of address lines A1 of the address lines between the memory controller 1200 and the DRAM 1100. The row address RA2b may be transferred through the second address line A2 of the address lines between the memory controller 1200 and the DRAM 1100.

At a fourth clock cycle C4, the memory controller 1200 may output a read or write command WRb/RDb and a column address CAb to the DRAM 1100. The column address CAb may be transferred through the first set of address lines A1 of the address lines between the memory controller 1200 and the DRAM 1100. The spare access command ESC CMD may be output if at least one of the row addresses RA1a and RA2a and the column address CAa corresponds to defect information (e.g., at least one of defective addresses) of the DRAM 1100.

The fourth clock cycle C4 may be timing corresponding to an additive latency AL of the read or write command WRb/RDb and the column address CAb. Thus, the memory controller 1200 may output a spare access command ESC CMD to the DRAM 1100.

The column address CAb may be output through the first set of address lines A1, and the spare access command ESC CMD may be output through the second address line A2. Thus, the read or write command WRb/RDb and the column address CAb may be output together with the spare access command ESC CMD.

As described above, the spare access command ESC CMD may be output through the second address line which is not used when the column address CAa or CAb is output. Thus, the spare access command ESC CMD may be simultaneously output without collision with the column address CAb and the read or write command WRb/RDb.

In example embodiments, the spare access command ESC CMD may be output through an A11 or A13 address node or address line.

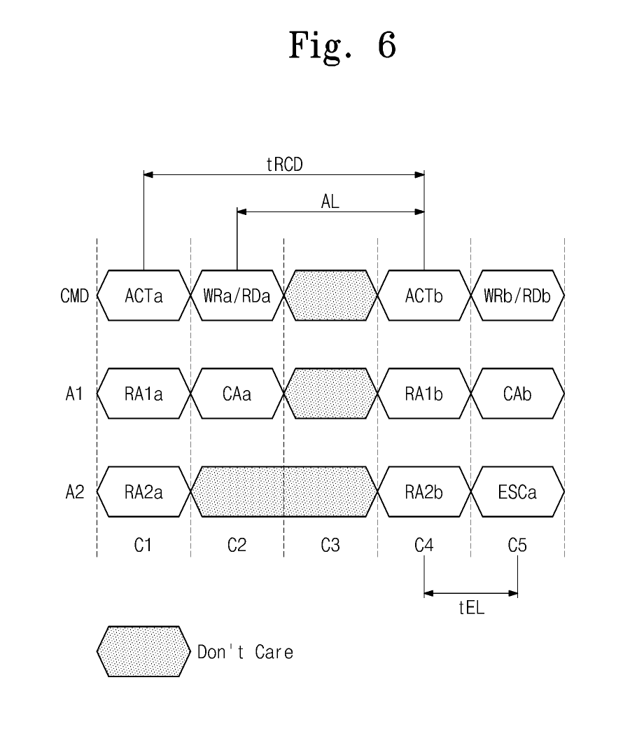

FIG. 6 is a timing diagram schematically illustrating a third embodiment where a memory controller 1200 accesses a DRAM 1100. In FIG. 6, there is illustrated an example where information associated with an address corresponds to defect information and collision exists (operation S260 of FIG. 3).

Referring to FIGS. 1 and 6, at a first clock cycle C1, a memory controller 1200 may output an active command ACTa and row addresses RA1a and RA2a to a DRAM 1100.

At a second clock cycle C2, the memory controller 1200 may output a read or write command WRa/RDa and a column address CAa to the DRAM 1100.

At a fourth clock cycle C4, the memory controller 1200 may output an active command ACTb and row addresses RA1b and RA2b to the DRAM 1100. The row address RA1b may be transferred through a first set of address lines A1 of address lines between the memory controller 1200 and the DRAM 1100. The row address RA2b may be transferred through a second address line A2 of the address lines between the memory controller 1200 and the DRAM 1100.

The fourth clock cycle C4 may be timing corresponding to an additive latency AL of the read or write command WRa/RDa and the column address CAa.

The spare access command ESC CMD may be output if at least one of the row addresses RA1 a and RA2a and the column address CAa corresponds to defect information (e.g., at least one of defective addresses) of the DRAM 1100.

The row addresses RA1b and RA2b may be output through the first set of address lines and the second address line A1 and A2. The spare access command ESC CMD may be output through the second address line. Thus, collision may be generated between the row addresses RA1b and RA2b and the spare access command ESC CMD.

For example, the memory controller 1200 may output the spare access command ESC CMD at timing delayed by a spare access latency tEL with respect to an additive latency AL. If the spare access command ESC CMD is delayed and output, it may be possible to prevent collision between the spare access command ESC CMD and the row addresses RA1b and RA2b. In example embodiments, the spare access latency tEL may be one clock cycle.

At a fifth clock cycle C5, the memory controller 1200 may output a read or write command WRb/RDb and a column address CAb to the DRAM 1100. The column address CAb may be transferred through the first address lines A1 of the address lines between the memory controller 1200 and the DRAM 1100.

The fifth clock cycle C5 may be timing delayed by the spare access latency tEL with respect to timing corresponding to the additive latency AL. Thus, the memory controller 1200 may output the spare access command ESC CMD to the DRAM 1100.

The column address CAb may be output through the first set of address lines A1, and the spare access command ESC CMD may be output through the second address line A2. Thus, the read or write command WRb/RDb and the column address CAb may be output together with the spare access command ESC CMD.

As described above, when the row addresses RA1b and RA2b are output at timing corresponding to the additive latency AL, the memory controller 1200 may output the spare access command ESC CMD at timing delayed by the spare access latency tEL with respect to timing corresponding to the additive latency AL. Thus, the spare access command ESC CMD may be simultaneously output without collision with the column address CAb and the read or write command WRb/RDb.

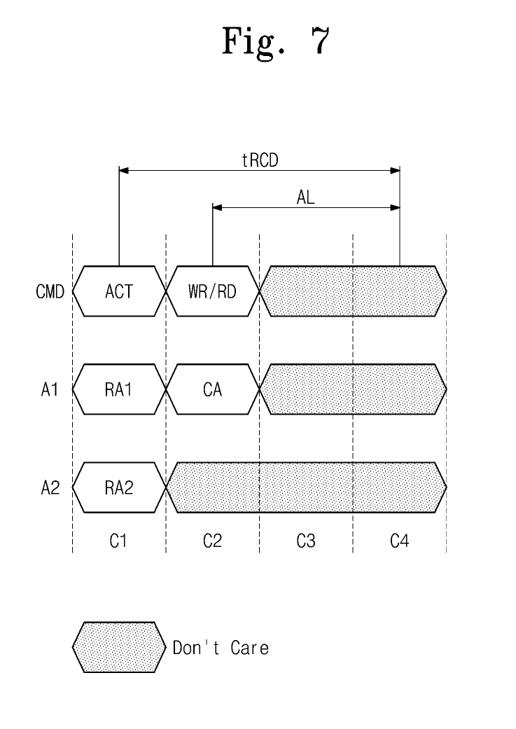

FIG. 7 is a timing diagram schematically illustrating a fourth embodiment where a memory controller 1200 accesses a DRAM 1100. In FIG. 7, there is illustrated an example where information associated with an address does not correspond to defect information (operation S230 of FIG. 3).

Referring to FIGS. 1 and 7, at a first clock cycle C1, a memory controller 1200 may output an active command ACT and row addresses RA1 and RA2 to a DRAM 1100.

At a second clock cycle C2, the memory controller 1200 may output a read or write command WR/RD and a column address CA to the DRAM 1100.

During an additive latency AL, the memory controller 1200 may compare the column address CA with defect information. Since information corresponding to the row addresses RA1 and RA2 and column address CA is not included in the defect information, the memory controller may skip a spare access command ESC CMD.

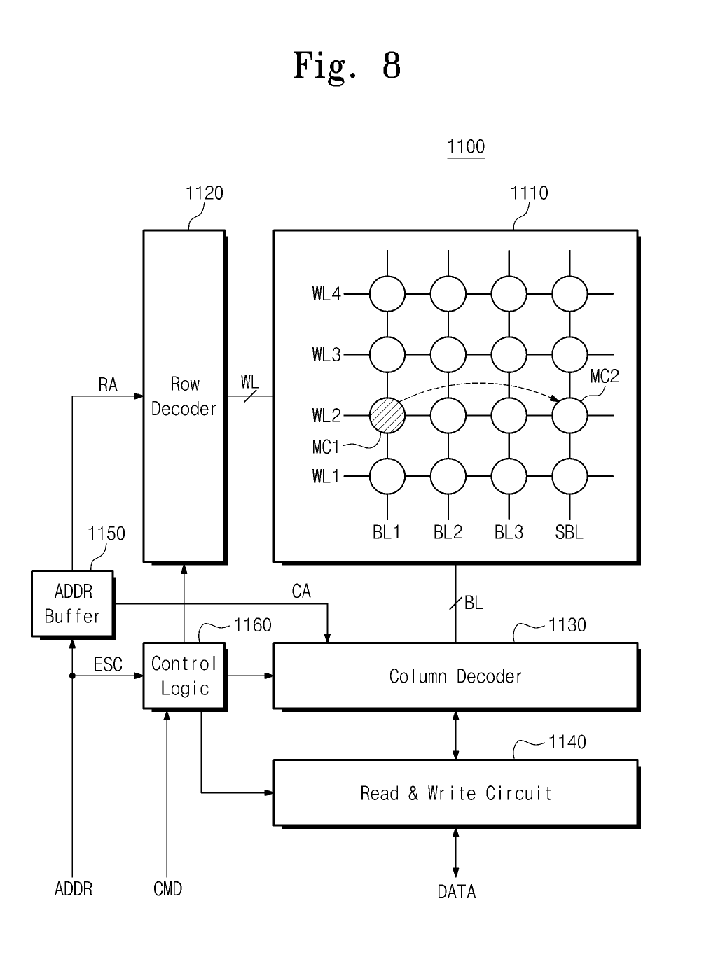

FIG. 8 is a block diagram schematically illustrating a DRAM 1100 according to example embodiments. Referring to FIGS. 1 and 8, a DRAM 1100 may include a memory cell array 1110, a row decoder 1120, a column decoder 1130, a read/write circuit 1140, an address buffer 1150, and control logic 1160.

The memory cell array 1110 may include a plurality of memory cells arranged along rows and columns. Rows of the memory cells may be connected to the row decoder 1120 through word lines, and columns of memory cells may be connected to the column decoder 1130 through bit lines.

The memory cells may be divided into normal memory cells and spare memory cells. The normal memory cells may be memory cells connected to bit lines BL1 to BL4. The spare memory cells may be memory cells connected to a spare bit line SBL. The normal memory cells may be memory cells accessed by an external device. The spare memory cells may be memory cells used to replace defected memory cells of the normal memory cells.

The row decoder 1120 may be connected to the memory cell array 1110 through the word lines. The row decoder 1120 may operate in response to a control of the control logic 1160. The row decoder 1120 may receive a row address RA from the address buffer 1150. Based on the row address RA, the row decoder 1120 may select one of the word lines.

The column decoder 1130 may be connected to the memory cell array 1110 through the bit lines BL. The column decoder 1130 may operate in response to a control of the control logic 1160. The column decoder 1130 may receive a column address CA from the address buffer 1150. Based on the column address CA, the column decoder 1130 may select at least one of the bit lines BL.

The read/write circuit 1140 may be connected to the column decoder 1130. The read/write circuit 1140 may be configured to exchange data with an external device (e.g., a memory controller 1200). The read/write circuit 1140 may operate according to a control of the control logic 1160. The read/write circuit 1140 may perform a read or write operation through the at least one bit line selected by the column decoder 1130. The read/write circuit 1140 may include a sense amplifier or a write driver.

The address buffer 1150 may receive an address ADDR from the external device (e.g., the memory controller 1200). The address buffer 1150 may output the received address to the row decoder 1120 or the column decoder 1130 according to a control of the control logic 1160.

The control logic 1160 may control an overall operation of the DRAM 1100. The control logic 1160 may be configured to receive a command CMD from the external device (e.g., the memory controller 1200). For example, the control logic 1160 may receive the command CMD through command lines.

The control logic 1160 may receive a spare access command ESC CMD. For example, the control logic 1160 may receive the spare access command ESC CMD through address lines. The control logic 1160 may receive the spare access command ESC CMD through address lines which are used at an input of the row address RA and are not used at an input of the column address CA.

The row address RA and the column address CA may be received from the external device (e.g., the memory controller 1200). The row decoder 1120 may select a word line according to the row address RA. The column decoder 1130 may select at least one bit line according to the column address CA. In example embodiments, the row address RA may correspond to a second word line WL2, and the column address CA may correspond to a first bit line BL1. At this time, a memory cell MC1 may be selected by the row decoder 1120 and the column decoder 1130.

In the event that the memory cell MC1 is a defective memory cell, defect information stored at a nonvolatile memory 1210 of the memory controller 1200 may include information on an address of the memory cell MC1. Thus, a spare access command ESC CMD may be issued.

In response to the spare access command ESC CMD, the control logic 1160 may control the column decoder 1130 such that a predetermined spare bit line SBL is selected instead of a bit line corresponding to the column address CA. For example, a memory cell MC2 connected to a word line WL2 corresponding to the row address RA and the spare bit line SBL may be accessed instead of the memory cell MC1 corresponding to the row address RA and the column address CA.

As described above, the memory controller 1200 may be configured to compare an address and defect information and to output the spare access command ESC CMD based on the comparison result. The DRAM 1100 may access a spare memory cell instead of a normal memory cell in response to the spare access command ESC CMD. Thus, a repair operation may be performed according to defect information stored at the memory controller 1200, and defected memory cells generated after the DRAM 1100 is repaired may be repaired.

In example embodiments, an additive latency AL and a spare access latency tEL may be programmed at the DRAM 1100 by the memory controller 1200. The additive latency AL and the spare access latency tEL may be programmed at a mode register (MR) or a special function register (SFR) of the DRAM 1100.

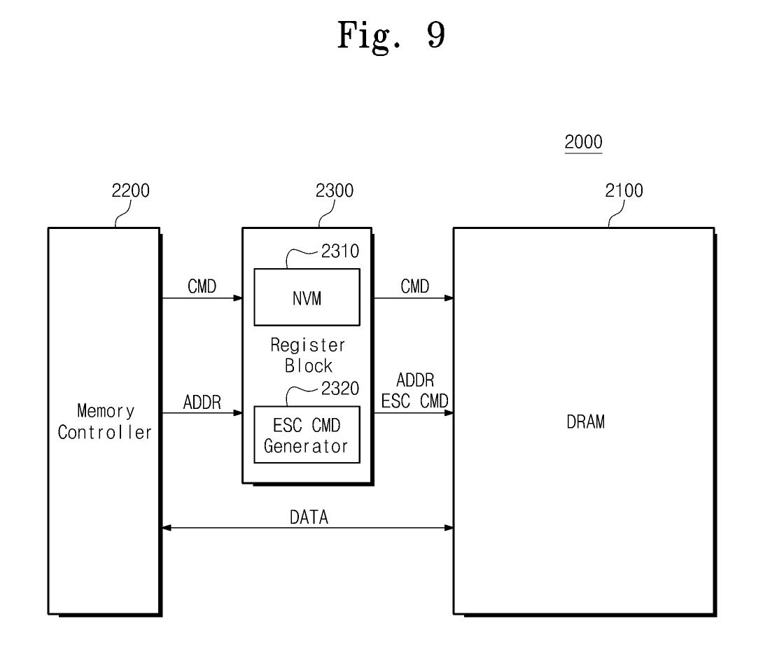

FIG. 9 is a block diagram schematically illustrating a memory system 2000 according to another exemplary embodiment. Referring to FIG. 9, a memory system 2000 may include a DRAM 2100, a memory controller 2200, and a register block 2300. As compared to a memory system 1000 of FIG. 1, the memory system 2000 may further comprise the register block 2300. A duplicated description between the memory system 2000 of FIG. 9 and the memory system 1000 of FIG. 1 may be omitted.

The register block 2300 may receive a command CMD and an address ADDR from the memory controller 2200. The register block 2300 may send the command CMD and the address ADDR to the DRAM 2100. The register block 2300 may buffer the command CMD and the address ADDR between the memory controller 2200 and the DRAM 2100. The register block 2300 may further send a spare access command ESC CMD to the DRAM 2100.

The register block 2300 may include a nonvolatile memory 2310 and a spare access command generator 2320. The nonvolatile memory 2310 may be configured to store defect information. The spare access command generator 2320 may compare the address ADDR with the defect information, and may output the spare access command ESC CMD to the DRAM 2100 according to the comparison result. As described with reference to a memory controller 1200 in FIGS. 1 to 8, the register block 2300 may manage defect information and issue the spare access command ESC CMD.

In example embodiments, although the register block 2300 is provided, the memory controller 2200 can be configured to manage defect information and to issue the spare access command ESC CMD. In this case, as described with reference to FIG. 1, the nonvolatile memory 2310 and the spare access command generator 2320 may be provided in the memory controller 2200. The register block 2300 may buffer the address ADDR, the command CMD and the spare access command ESC CMD between the memory controller 2200 and the DRAM 2100.

In example embodiments, an additive latency AL and a spare access latency tEL may be programmed at the DRAM 2100 by the memory controller 2200 or the register block 2300. The additive latency AL and the spare access latency tEL may be programmed at a mode register (MR) or a special function register (SFR) of the DRAM 2100.

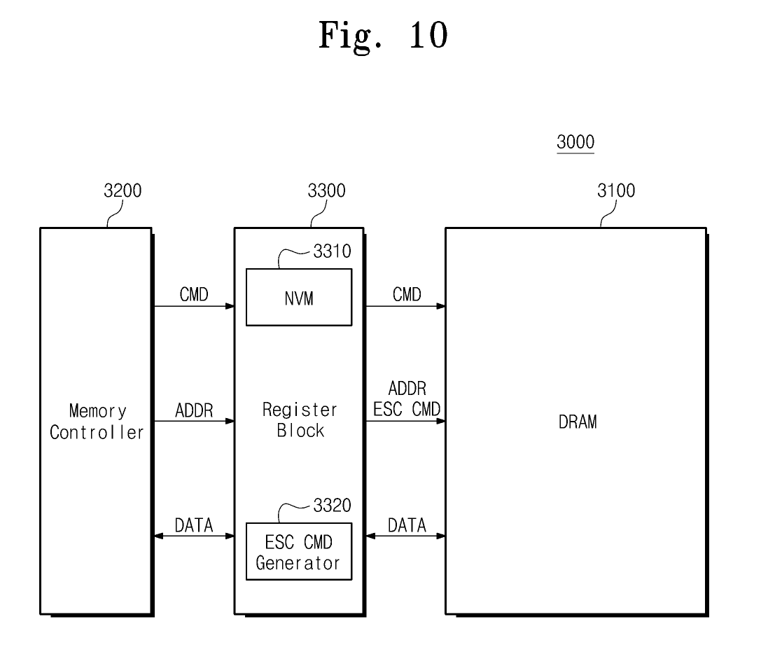

FIG. 10 is a block diagram schematically illustrating a memory system 3000 according to still another exemplary embodiment of the inventive concept. Referring to FIG. 10, a memory system 3000 may include a DRAM 3100, a memory controller 3200, and a register block 3300. As compared to a memory system 1000 of FIG. 1, the memory system 3000 may further comprise the register block 3300. A duplicated description between the memory system 3000 of FIG. 10 and the memory system 1000 of FIG. 1 may be omitted.

The register block 3300 may receive a command CMD and an address ADDR from the memory controller 3200 and exchange data with the memory controller 3200. The register block 3300 may send the command CMD and the address ADDR to the DRAM 3100 and exchange data with the DRAM 3100. The register block 3300 may buffer the command CMD and the address ADDR between the memory controller 3200 and the DRAM 3100. The register block 3300 may further send a spare access command ESC CMD to the DRAM 3100.

The register block 3300 may include a nonvolatile memory 3310 and a spare access command generator 3320. The nonvolatile memory 3310 may be configured to store defect information. The spare access command generator 3320 may compare the address ADDR with the defect information, and may output the spare access command ESC CMD to the DRAM 3100 according to the comparison result. As described with reference to a memory controller 1200 in FIGS. 1 to 8, the register block 3300 may manage defect information and issue the spare access command ESC CMD.

In example embodiments, although the register block 3300 is provided, the memory controller 3200 can be configured to manage defect information and to issue the spare access command ESC CMD. In this case, as described with reference to FIG. 1, the nonvolatile memory 3310 and the spare access command generator 3320 may be provided in the memory controller 3200. The register block 3300 may buffer the address ADDR, the command CMD and the spare access command ESC CMD between the memory controller 3200 and the DRAM 3100.

In example embodiments, an additive latency AL and a spare access latency tEL may be programmed at the DRAM 3100 by the memory controller 3200 or the register block 3300. The additive latency AL and the spare access latency tEL may be programmed at a mode register (MR) or a special function register (SFR) of the DRAM 3100.

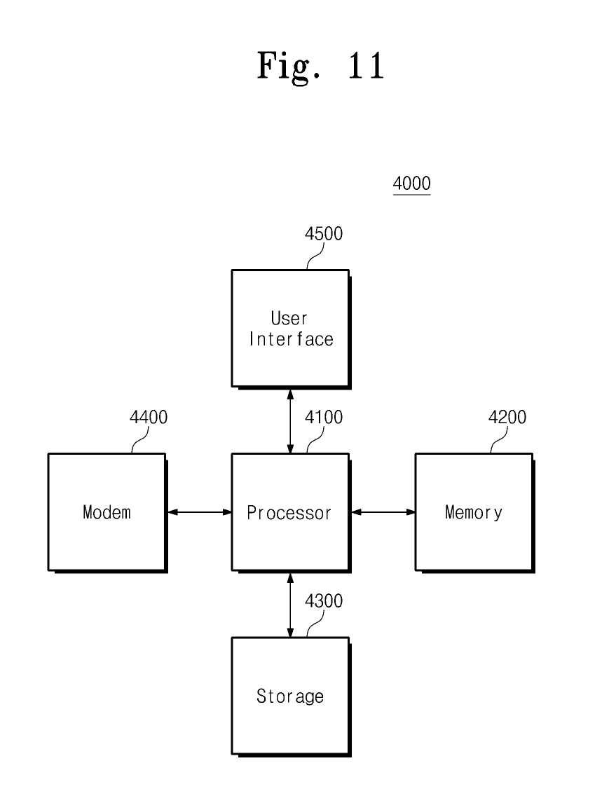

FIG. 11 is a block diagram schematically illustrating a computing device 4000 according to certain embodiments. Referring to FIG. 11, a computing device 4000 may include a processor 4100, a memory 4200, storage 4300, a modem 4400, and a user interface 4500.

The processor 4100 may control an overall operation of the computing device 4000, and may perform a logical operation. The processor 4100 may be formed of a system-on-chip (SoC). The processor 4100 may be a general purpose processor or an application processor.

The memory 4200 may communicate with the processor 4100. The memory 4200 may be a working memory (or, a main memory) of the processor 4100 or the computing device 4000. The memory 4200 may include a volatile memory such as a static RAM, a dynamic RAM, a synchronous DRAM, or the like or a nonvolatile memory such as a flash memory, a phase-change RAM (PRAM), a magnetic RAM (MRAM), a resistive RAM (RRAM), a ferroelectric RAM (FRAM), or the like.

The memory 4200 may operate according to a spare access command ESC CMD as described with reference to FIGS. 1 to 10. A memory controller may be provided in the processor 4100 or integrated with the memory 4200. The memory controller may be provided between the processor 4100 and the memory 4200.

The memory 4200 may include at least one memory module or at least one memory package.

The storage 4300 may be main storage of the computing system 4000. The storage 4300 may be used to store data for a long time. The storage 4300 may include a hard disk drive or a nonvolatile memory such as a flash memory, a PRAM (Phase-change RAM), an MRAM (Magnetic RAM), an RRAM (Resistive RAM), an FRAM (Ferroelectric RAM) or the like.

In example embodiments, the memory 4200 and the storage 4300 may be formed of a nonvolatile memory of a same type. In this case, the memory 4200 and the storage 4300 may be integrated into a semiconductor integrated circuit.

The modem 4400 may communicate with an external device according to a control of the processor 4100. For example, the modem 4400 may communicate with the external device in a wire or wireless manner. The modem 4400 may communicate based on at least one of wireless communications manners such as LTE (Long Term Evolution), WiMax, GSM (Global System for Mobile communication), CDMA (Code Division Multiple Access), Bluetooth, NFC (Near Field Communication), WiFi, RFID (Radio Frequency Identification, and so on or wire communications manners such as USB (Universal Serial Bus), SATA (Serial AT Attachment), SCSI (Small Computer Small Interface), Firewire, PCI (Peripheral Component Interconnection), and so on.

The user interface 4500 may communicate with a user according to a control of the processor 4100. For example, the user interface 4500 may include user input interfaces such as a keyboard, a keypad, a button, a touch panel, a touch screen, a touch pad, a touch ball, a camera, a microphone, a gyroscope sensor, a vibration sensor, and so on. The user interface 4500 may further include user output interfaces such as an LCD, an OLED (Organic Light Emitting Diode) display device, an AMOLED (Active Matrix OLED) display device, an LED, a speaker, a motor, and so on.

While the disclosure has been described with reference to exemplary embodiments, it will be apparent to those skilled in the art that various changes and modifications may be made without departing from the spirit and scope of the present invention. Therefore, it should be understood that the above embodiments are not limiting, but illustrative.

What is claimed is:

1. A method of accessing a semiconductor memory, the method comprising:
outputting a row address and an active command to the semiconductor memory;
outputting a column address and a read or write command to the semiconductor memory; and
outputting a spare access command to the semiconductor memory to access data from a spare memory cell at a timing based on an additive latency of the semiconductor memory.

2. The method of claim 1, wherein outputting the spare access command comprises:
comparing the row address or the column address with defect information; and
if the row address or the column address corresponds to the defect information, outputting the spare access command to the semiconductor memory based on the additive latency.

3. The method of claim 1, wherein outputting the spare access command comprises:
determining the row address corresponds to the defective address and outputting an additional row address to the semiconductor memory at timing synchronized with the additive latency; and
outputting the spare access command to the semiconductor memory at timing delayed with respect to the additive latency.

4. The method of claim 3, wherein the row address or the column address is output through a first set of address lines, and
wherein at least one of the additional row address and the spare access command is output through a second set of address lines different from the first set of address lines.

5. The method of claim 2, wherein the defect information comprises a set of stored defective addresses of the semiconductor memory.

6. The method of claim 1, further comprising outputting the spare access command to the semiconductor memory through an A11 or A13 address line.

7. A semiconductor circuit which transfers row addresses, column addresses and commands, comprising:
a memory configured to store defect information of a memory device; and
a command generator configured to output a first access command corresponding to a row address, to compare the row address with the defect information and to output a spare access command to access data from a spare memory cell associated with the defect information at a timing based on an additive latency.

8. The semiconductor circuit of claim 7, wherein the command generator is configured to output from the semiconductor circuit the spare access command in synchronization with the additive latency.

9. The semiconductor circuit of claim 8, wherein row addresses and column addresses are output through a first set of address lines, and
wherein the spare access command is output through a second set of address lines different from the first set of address lines.

10. The semiconductor circuit of claim 7, wherein the command generator is configured to output the spare access command at timing delayed with respect to the additive latency.

11. The semiconductor circuit of claim 7, wherein the semiconductor circuit is a memory controller and the memory is a nonvolatile memory.

12. The semiconductor circuit of claim 7, wherein the memory is configured to receive the defect information from a memory controller.

13. The semiconductor circuit of claim 7, wherein the memory includes a fuse circuit or an electrically programmable nonvolatile memory.

14. A memory system comprising:
the semiconductor circuit of claim 7; and
the memory device operatively connected to the semiconductor circuit to receive the row addresses, the column addresses and the spare access command from the semiconductor circuit.

15. A method of operating a memory system, the method comprising:
providing an active command and a row address at a first clock cycle to a memory device;
providing a read or write command and a column address at a second clock cycle after the first clock cycle to the memory device;
determining the row address at the first clock cycle or the column address at the second clock cycle corresponds to a defective address of the memory device; and
providing a spare access command at an nth clock cycle to access data from a spare memory cell associated with the defective address to the memory device,
wherein n being an integer and determined based on an additive latency AL.

16. The method of claim 15, further comprising providing an additional row address to the memory device,
wherein providing of the row address and the column address is issued through a first set of address lines, and
wherein providing of the additional row address and the spare access command are issued through a second set of address lines different from the first set of address lines.

17. The method of claim 16, wherein n is determined in response to determining the providing of the additional row address to the memory device at the end of clock cycle of the additive latency AL.

18. The method of claim 17, wherein n is determined in synchronized with the additive latency if no additional row address is provided at the end of clock cycle of the additive latency AL.

19. The method of claim 17, wherein n is determined at timing delayed at least one clock cycle with respect to the additive latency if an additional row address is provided at the end of clock cycle of the additive latency AL.
